(19) United States
(12) Patent Application Publication
(10) Pub. No.: US 2025/0246434 A1
(43) Pub. Date: Jul. 31, 2025

(54) METAL SILICIDE CONTACT FORMATION

(71) Applicant: Lam Research Corporation, Fremont, CA (US)

(72) Inventors: Sang-Hyeob Lee, Fremont, CA (US); Ishtak Karim, San Jose, CA (US); Benjamin A. Bonner, San Jose, CA (US); Hee Sook Park, San Ramon, CA (US); Kaihan Abidi Ashtiani, Cupertino, CA (US)

(21) Appl. No.: 18/854,370

(22) PCT Filed: Apr. 25, 2023
(86) PCT No.: PCT/US2023/019800

§ 371 Date: Oct. 4, 2024

Related U.S. Application Data
(60) Provisional application No. 63/363,786, filed on Apr. 28, 2022.

(51) Int. Cl. H01L 21/285; C23C 16/02; C23C 16/04; C23C 16/14; C23C 16/42; C23C 16/455; C23C 16/52; C23C 16/56; H01L 21/02

(52) U.S. Cl. CPC H01L 21/28518; C23C 16/0227; C23C 16/045; C23C 16/14; C23C 16/42; C23C 16/45525; C23C 16/52; C23C 16/56; H01L 21/02068; H01L 21/28562

(57) ABSTRACT

Provided are metal silicide contact forming processes including providing a substrate having a bottom crystalline silicon and di-electric sidewalls. This may be followed by metal layer deposition to form metal layer selectively on the bottom crystalline silicon using a metal halide precursor and a reducing agent. A ratio of a reducing agent flow rate to a metal halide precursor flow rate is at least 10:1, or 10:1-10,000:1. After the metal layer deposition, the substrate is annealed to convert the metal layer to a metal silicide layer without any substrate contamination.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Metal silicides may be formed in the fabrication of various semiconductor devices. For example, dynamic random-access memory (DRAM) may include metal silicide contacts on crystalline silicon. Formation of silicides for complex structures such as 3D-DRAM structures can be challenging.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided are methods of forming metal silicide contacts in features that including a bottom crystalline silicon surface and oxide or nitrides sidewall surfaces. The methods may involve depositing tungsten (W) or molybdenum (Mo) on the bottom crystalline silicon without depositing W or Mo on the sidewall surfaces. Subsequently, the W or Mo film may be annealed to form a tungsten silicide (WSiₓ) or molybdenum silicide (MoSiₓ). The annealing may be conducted in-situ without breaking vacuum. In some embodiments, annealing is performed without a capping layer.

One aspect of the disclosure relates to a method including providing a feature having a feature bottom and feature sidewalls. The feature bottom includes a crystalline silicon surface and the feature sidewalls includes oxide or nitride surfaces. The method further includes exposing the feature to a metal halide precursor flow including a metal halide precursor and a reducing agent flow including a reducing agent to thereby selectively form a metal layer on the crystalline silicon surface. The metal halide precursor flow and the reducing agent flow have a flow rate ratio of at least 10:1. The method still further includes annealing the metal layer to form a metal silicide layer from the metal layer.

In some embodiments, the method further includes, prior to exposing the feature to the metal halide precursor flow, cleaning the feature bottom and the feature sidewalls.

In some embodiments, the metal halide precursor includes a metal chloride or a metal fluoride.

In some such embodiments, the metal halide precursor includes tungsten hexafluoride, tungsten pentachloride, molybdenum hexafluoride, or molybdenum pentachloride.

In some embodiments, the metal layer includes tungsten or molybdenum.

In some embodiments, the reducing agent includes hydrogen, silane, or a combination thereof.

In some embodiments, the flow rate ratio ranges from about 10:1 to about 10,000:1.

In some embodiments, the thickness of the metal layer ranges in thickness from about 2 nm to about 20 nm.

In some embodiments, the crystalline silicon of the crystalline silicon surface is doped or undoped single crystalline silicon crystal or doped or undoped polycrystalline silicon.

In some embodiments, the annealing of the metal layer is undertaken between about 500° C. and about 800° C.

In some embodiments, the annealing of the metal layer is undertaken under pressures ranging 1-100 Torr.

In some embodiments, the metal halide precursor flow and the reducing agent flow are alternated to form the metal layer by atomic layer deposition (ALD).

In some embodiments, the metal halide precursor flow and the reducing agent flow are co-flowed to form the metal layer by chemical vapor deposition (CVD).

In some embodiments, the metal halide precursor flow is pulsed and the reducing agent flow is continuous to form the metal layer by pulsed CVD.

In some embodiments, the metal silicide layer forms an ohmic contact with the crystalline silicon surface.

In some embodiments, the metal silicide layer includes tungsten silicide or molybdenum silicide.

Another aspect of the disclosure relates to a method including providing a feature having a feature bottom and feature sidewalls. The feature bottom includes a crystalline silicon surface and the feature sidewalls include oxide or nitride surfaces. The method further includes exposing the feature to a first metal halide precursor flow including a first metal halide precursor, and a first reducing agent flow including a first reducing agent to thereby selectively form a first metal layer on the crystalline silicon surface. The first metal halide precursor flow and the first reducing agent flow have a flow rate ratio of at least 10:1. The method still further includes providing a second metal halide precursor flow including a second metal halide precursor, and a second reducing agent flow including a second reducing agent to the first metal layer to form a second metal layer. The second metal halide precursor flow and the second reducing agent flow have a flow rate ratio of at least 10:1. The method still further includes annealing the second metal layer to form a metal silicide layer.

In some embodiments, the first metal halide precursor and the second metal halide precursor are selected respectively from tungsten hexafluoride, tungsten pentachloride, molybdenum hexafluoride, and molybdenum pentachloride.

In some embodiments, wherein the first reducing gent and the second reducing agent are selected respectively from hydrogen, silane, or a combination thereof.

In some embodiments, the metal silicide layer comprises tungsten silicide or molybdenum silicide.

In some embodiments, the first and second metal halide precursors and the first and second reducing agents are supplied by chemical vapor deposition or atomic layer deposition.

These and other aspects are discussed further below with reference to the drawings.

### BRIEF DESCRIPTION OF DRAWINGS

FIG. 1A is a schematic diagram showing a cross-sectional depiction of recessed lateral contacts in a 3D dynamic random-access memory (3D-DRAM) prior to metal silicide layer formation according to various embodiments. FIG. 1B is a schematic diagram showing a cross-sectional depiction of lateral contacts in a 3D-DRAM structure after forming a metal silicide layers and barrier metal/bottom electrodes according to various embodiments.

FIG. 2 is a schematic diagram showing a cross-sectional depiction of features in a vertical structure according to various embodiments.

FIG. 3 is a process flow diagram showing certain operations in methods according to various embodiments.

FIG. 4A is a schematic diagram showing providing tungsten hexafluoride (WF₆) and hydrogen (H₂) to the surface of silicon (Si) according to various embodiments.

FIG. 4B is a schematic diagram showing a cross-sectional depiction of tungsten (W) layer formation on Si using WF₆/H₂ according to various embodiments.

FIG. 5 is a schematic diagram showing a cross-sectional depiction of W metal layer formation using WF₆/H₂ according to various embodiments.

FIGS. 6A and 6B are schematic diagrams showing cross-sectional depictions of W metal layer formation using WF₆/SiH₄ and WF₆/H₂ according to various embodiments.

FIGS. 7A and 7B are schematic diagrams showing cross-sectional depictions of W metal layer formation using WF₆/H₂ and WCl₅/H₂ according to various embodiments.

FIG. 8A is an example of a flow sequence for a pulsed chemical vapor deposition (CVD) process that may be used to form a metal layer.

FIG. 8B is an example of a flow sequence for a co-flow CVD process that may be used to form a metal layer.

FIG. 8C is another example of a flow sequence for a co-flow CVD process that may be used to form a metal layer.

FIG. 8D is an example of a flow sequence for an atomic layer deposition (ALD) process that may be used to form a metal layer.

FIG. 9 shows an example of apparatus that may be used to perform the methods described herein.

FIG. 10A shows an example of apparatus that may be used to perform the methods described herein.

FIG. 10B shows an example of apparatus that may be used to perform the methods described herein.

### DESCRIPTION

Provided are methods of forming metal silicide contacts with crystalline silicon. The methods involve forming a metal layer including tungsten (W) or molybdenum (Mo) followed by annealing to convert the metal layer to a metal silicide layer. A metal layer may be formed in a pulsed chemical vapor deposition (CVD), co-flow CVD, or atomic layer deposition (ALD) process. In some embodiments, the annealing is performed without first forming a capping layer.

Forming electrical contacts in semiconductor device fabrication can involve forming metal layers in recessed features with tungsten, molybdenum, or other electrically conductive materials. Features may include holes, trenches, and vias. Metal layers in features may be annealed to form a metal silicide. The metal silicide may form an ohmic contact with semiconducting silicon, lowering contact resistance. For example, W provides a low resistance and low stress layer and has a thermal expansion coefficient close to that of silicon. Also, tungsten has high resistance to electromigration.

When a metal layer such as tungsten is formed from halide precursors, uncontrolled metal growth may result in a non-uniform interface between the metal and silicon, depending on the nature and reactions of competing precursors and other reactants. These defects may be responsible for non-uniform contact resistances in contacts or semiconductor device failure. These defects can be critical for devices with smaller technology nodes and more complex patterning structures where uniform metal growth is a significant challenge.

Uniform metal growth can be a particular challenge in 3D dynamic random-access memory (3D DRAM) structures, which may include hundreds of lateral features stacked in a vertical direction. 3D DRAM includes increased number of contacts while the contact area is reduced compared to prior semiconductor devices. Deposition in 3D DRAM structures by methods such as sputtering a metal target in a physical vapor deposition (PVD) method can be particularly challenging with most of the structure out of the line-of-sight of the deposition species. Plasma-based methods such as plasma-enhanced CVD (PECVD) can also have poor step coverage in complex geometries. Uniform metal growth can also be challenging in vertical structures, such as in vertical DRAM or logic structures that include a plurality of vertical features. In particular, deposition in tall or high aspect ratio structures formed in many stacked layers can be challenging.

In some embodiments, the methods described herein includes metal layer deposition suing a metal halide precursor. In some embodiments, the methods described herein include deposition of a thin tungsten layer using a tungsten halide precursor. Tungsten halide precursors are given by the formula WX_{z}, where X is a halogen (fluorine (F), chlorine (Cl), bromine (Br), or iodine (I)) and z is 2, 3, 4, 5, or 6. Examples of WX_{z} precursors include tungsten hexafluoride (WF₆), tungsten hexachloride (WCl₆), and tungsten pentachloride (WCl₅). In some embodiments, the desired thickness of W layer may range from about 3 nm to 5 nm.

In some embodiments, the process described here includes deposition of a thin molybdenum layer using a molybdenum halide precursor. Molybdenum halide precursors are given by the formula MoX_{z}, where X is a halogen (fluorine (F), chlorine (Cl), bromine (Br), or iodine (I)) and z is 2, 3, 4, 5, or 6. Examples of MoX_{z} precursors include molybdenum hexafluoride (MoF₆). Molybdenum chloride precursors are given by the formula MoClₓ, where x is 2, 3, 4, 5, or 6, and include molybdenum dichloride (MoCl₂), molybdenum trichloride (MoCl₃), molybdenum tetrachloride (MoCl₄), molybdenum pentachloride (MoCl₅), and molybdenum hexachloride (MoCl₆). In some embodiments, the desired thickness of Mo layer may range from about 3 to 5 nm.

Using a non-oxygen-containing precursor to deposit the initial W or Mo layer prevents oxidation of the feature's surfaces. It also prevents oxygen from being incorporated into the initial W or Mo layer. Oxidation increases contact resistance. The lack of oxidation and oxygen incorporation ensures the contact resistance remains low.

Examples of reducing agents include hydrogen (H₂), silane (SiH₄), diborane (B₂H₆), germane (GeH₄), ammonia (NH₃), and hydrazine (N₂H₄). In some embodiments, more than one reducing agents with a predetermined mixing ratio may be pulsed together with tungsten halide precursor or molybdenum halide precursor to form tungsten or molybdenum metal.

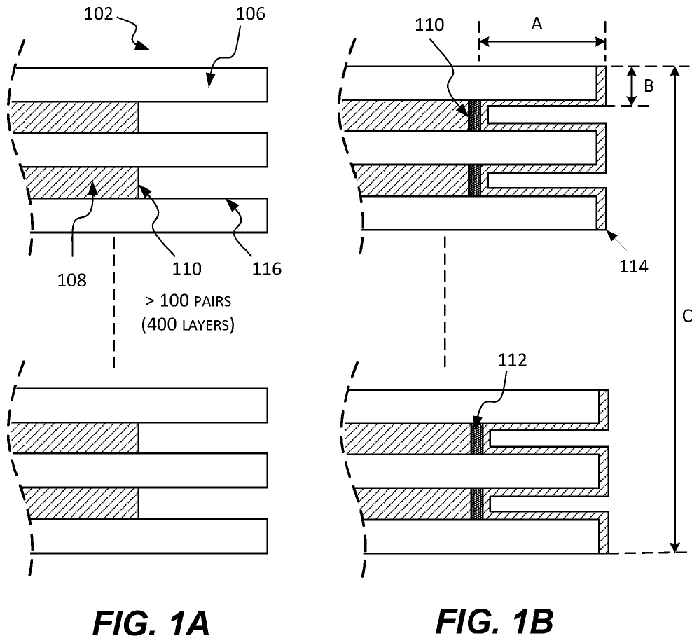

Schematic diagrams showing cross-sectional features in a 3D DRAM structure according to various embodiments are illustrated in FIGS. 1(a) and 1(b). A recessed feature 102 has sidewalls 106 with sidewall surfaces 116 and a bottom including crystalline silicon 108. Crystalline silicon 108 includes a crystalline silicon surface 110. The recessed feature 102 may be a hole or trench, for example. The sidewalls 106 may be made of one or more layers. Sidewalls 106 include a dielectric layer. Examples of dielectric materials include oxides, such as silicon oxide (SiO₂) and aluminum oxide (Al₂O₃); nitrides, such as silicon nitride (SiN); carbides, such as nitrogen-doped silicon carbide (NDC) and oxygen-doped silicon carbide (ODC); and low k dielectrics, such as carbon-doped SiO₂.

The crystalline silicon 108 may extend from a first sidewall in the feature to a second sidewall in the feature and may be made of one or more layers. The crystalline silicon 108 of the crystalline silicon surface 110 may be doped or undoped single crystalline silicon or doped or undoped polycrystalline silicon. In one embodiment, crystalline silicon 108 may be doped polycrystalline silicon (doped poly Si). In some embodiments, the crystalline silicon 108 may form a gate electrode.

As shown in FIG. 1(b), a metal silicide layer 112 may be selectively formed on crystalline silicon 108 to form an ohmic contact. The thickness of a metal silicide layer 112 on crystalline silicon 108 may range from 2-10 nm. As described further below, a metal silicide layer 112 may be formed by forming a metal layer on crystalline silicon 108 followed by annealing to convert the metal layer to the metal silicide layer 112. In some embodiments, a metal layer may be formed using co-flow CVD, pulsed CVD, or ALD. Following formation of metal silicide layer 112, a conformal layer 114 may be formed on the metal silicide layer and the sidewall surfaces 116. In some embodiments, the conformal layer 114 may be a barrier layer or a bottom electrode of a capacitor. For example, titanium nitride (TiN) may be used as the barrier metal.

A challenge associated with the 3D-DRAM fabrication process described above is formation of metal silicide contact at the bottom of each recessed feature. Controlled selective formation of a metal layer on the bottom of each recessed feature before the metal layer is annealed to form a metal silicide layer can be difficult. Forming a metal layer selectively and uniformly on a Si may be affected by the dimension of the feature in which a metal layer is formed. In some embodiments, the recessed feature 102 has a depth ‘A’ of 100-300 nm, and a height ‘B’ of 10-30 nm, resulting in an aspect ratio (depth to height) of 3-30. These small feature sizes and high aspect ratios present challenges in forming a metal layer. In some embodiments, a 3D-DRAM structure may include a stack including more than 400 layers (features) that are vertically stacked. A total stack height ‘C’ may range about 6-12 μm. This configuration may also add additional complexity in achieving uniform, selective metal layer formation in each of the. In some embodiments, techniques that are used for selective deposition in other structures such as PVD or PECVD may not be suitable for uniformly and selectively forming metal layers in the recessed features of 3D-DRAM structures.

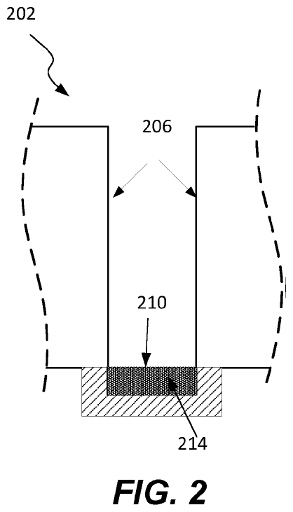

FIG. 2 is a schematic diagram showing cross-sectional features in a vertically-oriented feature. Such a feature may be used in DRAM or logic devices, for example. A device may include one or more recessed features 202 having a bottom surface 210 and sidewalls 206. Recessed features 202 may be extended in a vertical direction with respect to a substrate. Methods of selectively forming a metal silicide layer 214 from a metal layer described herein with respect to horizontally-oriented recessed features in 3D-DRAM structures may also be used for vertically-oriented structures such as those in DRAM and/or logic devices.

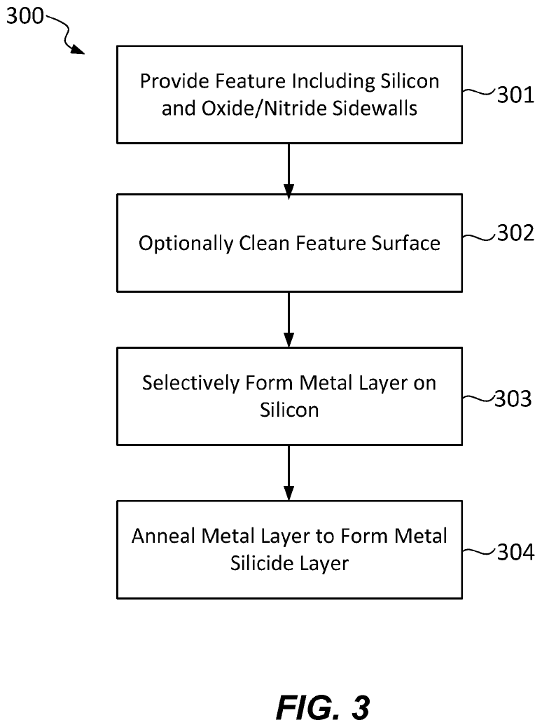

FIG. 3 is a process flow diagram illustrating a method to form a metal silicide ohmic contact with bottom crystalline silicon from a metal layer according to some embodiments. The metal layer may be tungsten (W) or molybdenum (Mo) film. Examples of applications include 3D-NAND, 3D-DRAM, 2D-DRAM, and logic applications.

Method 300 begins with providing a substrate including a feature having bottom silicon and oxide or nitride sidewalls, in which tungsten or molybdenum, depending on the device and/or processing requirements, is to be deposited in an operation 301. The substrate may be provided to a semiconductor processing tool. For example, the substrate may be positioned in a deposition chamber.

After providing a substrate including a feature having a bottom crystalline silicon and oxide or nitride sidewalls, an optional clean, operation 302, may be performed. The optional clean may be used to remove oxide layer formed on the feature's surfaces. In some embodiments, an atomic layer clean with a Cl-based plasma, a hydrogen fluoride (HF) vapor clean, an ammonium fluoride (NH₄F) clean, or a treatment using other reducing agents may be used to reduce oxide of Si at the feature bottom. In some embodiments, a hydrogen fluoride may be diluted to about 100:1 prior to cleaning. The optional clean may be performed in a deposition chamber. Alternately the optional clean may be done in a separate process prior to being provided to a deposition chamber.

Once the substrate is provided in a deposition chamber, a metal layer is formed in the feature in an operation 303. The metal layer, including tungsten or molybdenum layer, may be deposited by co-flow CVD, pulsed CVD, or ALD.

In co-flow CVD, a metal halide precursor and a reducing agent are continuously pulsed such that a substrate is continuously exposed to a metal halide precursor including but not limited to tungsten hexafluoride, tungsten pentachloride, molybdenum hexafluoride, or molybdenum pentachloride, and a reducing agent. The pulsing may continue until a metal layer with a predetermined thickness is formed. Alternately, a metal halide precursor and a reducing agent may be pulsed for a co-flow with a carrier gas such as inert gas purging between co-flow pulses. In a pulsed CVD process, a reducing agent may be flowed continuously while a metal halide precursor is pulsed with interval between pulses such that a substrate is exposed to a precursor during pulses. In an ALD process, a metal halide precursor, a reducing agent, and a carrier gas may be sequentially pulsed to form one cycle. In some embodiments, a pulsing cycle may include pulsing sequence of a metal halide precursor, a carrier gas, a reducing agent, and a carrier gas.

In some embodiments, pulsing may include more than one pulsing step. For example, more than one metal halide precursor and/or reducing agents may be sequentially pulsed in multiple pulsing steps. In a first pulsing step, a substrate may be exposed to a first precursor and a first reducing agent to form a first metal layer on the substrate. In a second pulsing step, the substrate may be exposed to a second precursor and a second reducing agent to form a second metal layer on the first metal layer formed in the first pulsing step. In some embodiments, a metal layer may be formed conformally to a bottom crystalline silicon. A metal layer may be about 2-20 nm thick in some embodiments. The metal layer may be about 2-10 nm thick, 3-7 nm thick, or 3-5 nm thick in some embodiments.

During metal layer formation, the temperature of the substrate and the pressure of a chamber may be controlled. For co-flow CVD and pulsed CVD, the substrate may be heated between 250° C.-350° C. In some embodiments, the chamber may be pressurized to at least 10 Torr, e.g., to at least 30 Torr, or to at least 50 Torr. For ALD process, in some embodiments, the substrate may be heated between 300° C.-500° C., e.g., between 350° C.-450° C. In some embodiments, the chamber may be pressurized to at least 10 Torr, e.g., to at least 30 Torr, or to at least 50 Torr.

After a metal layer is selectively deposited on the silicon surface, the feature is annealed to convert a metal layer to a metal silicide layer in operation 304. In some embodiments, the metal layer may be annealed by rapid thermal annealing. In some embodiments, the thickness of the metal silicide layer after annealing may range from about 2-10 nm. The annealing is generally conducted at between 500° C. and 800° C., e.g., between 500° C. and 700° C. . . . A metal layer may be annealed in-situ in a deposition chamber where a metal layer is formed, without exposing a metal layer to ambient atmosphere. In some embodiments, a substrate including metal layer is transferred from one pedestal to another pedestal for annealing. After metal silicide layer formation, a barrier layer (or bottom electrode) may be formed on the metal silicide layer and sidewalls.

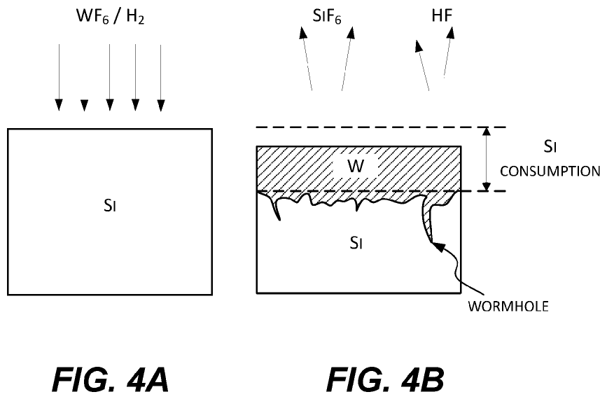

FIGS. 4A and 4B show schematic diagrams showing formation of tungsten layer from a reaction between WF₆/H₂ and Si according to various embodiments. For some embodiments, in a CVD or ALD process, when a metal halide precursor, e.g., tungsten hexafluoride (WF₆) and a reducing agent, e.g., hydrogen (H₂) reaches a crystalline silicon (FIG. 4A), the following reactions (1) and (2) may occur to form W layer on Si.

2WF₆(g)+3Si(s)→2W(s)+3SiF₄(g) (1)

WF₆(g)+3H₂(g)→W(s)+6HF(g) (2)

Reaction (1) may occur first followed by reaction (2). Alternately reactions (1) and (2) may occur substantially simultaneously with each other. According to reaction (1), WF₆(g) reacts with silicon to form tungsten and SiF₄ as a gas phase by-product. One or more atomic layers of silicon are consumed from the surface of silicon in a downward direction as tungsten layer is formed. As reaction (1) proceeds, thickness of silicon decreases and thickness of tungsten layer increases. The rate of reaction (1) may slow down as the tungsten layer forms a diffusion barrier between silicon and WF₆ until the diffusion layer prevents further reaction between silicon and WF₆. The tungsten layer may grow until the layer thickness reaches a self-limiting thickness, which in some embodiments may be about 10 nm (or 100 Å).

In some embodiments, reaction (1) may be reactive enough to have crystalline silicon excessively consumed. As a result, tungsten metal layer growth may result in formation of defects such as a ‘wormhole’ as illustrated in FIG. 4B. A wormhole defect may form from locally non-uniform encroachment of silicon. A wormhole defect can result in the formation of needle-shaped tungsten penetrating through crystalline silicon, which may cause a short-circuit in the device. Wormhole defects also can create non-uniform layer thickness of tungsten in the feature, which may increase variations in contact resistance in the device.

As reaction (1) slows with time, reaction (2) may predominate and eventually replaces reaction (1). In reaction (2), WF₆(g) is reduced by a reducing agent, e.g., H₂, to form a tungsten metal layer. Hydrogen fluoride (HF) may be a gas phase by-product. Tungsten metal formed from reaction (2) may be selectively formed on tungsten metal layer that is already formed according to reaction (1). That is, the tungsten is formed on the underlying tungsten without forming on a dielectric sidewall. Further, the tungsten metal layer according to reaction (2) does not substantially entail any defect formation such as wormholes that may be observed in reaction (1). In some embodiments, the thickness of tungsten layer and remaining silicon after reactions (1) and (2) may be less than the thickness of silicon thickness prior to reactions.

While reactions of Si and WF₆ and H₂ and WF₆ are described above for the purposes of explaining the considerations of competing reactions, the above explanation also applies to other metal halide precursors and reducing agents.

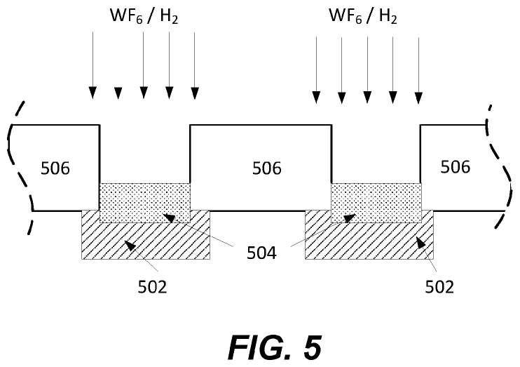

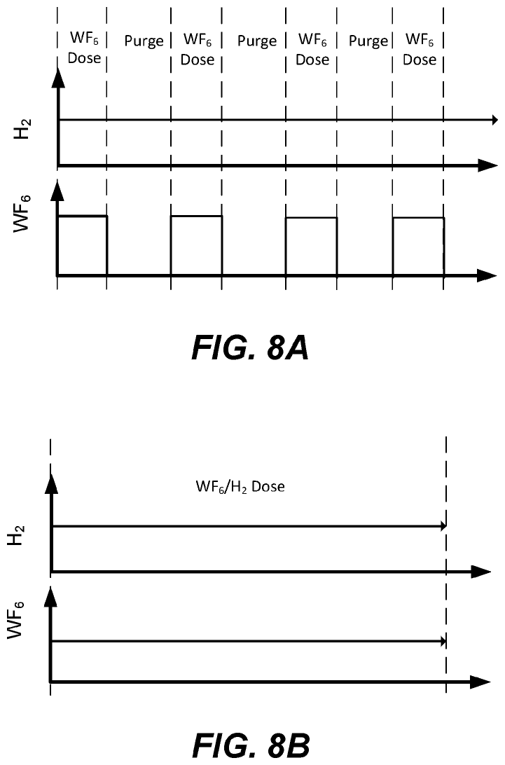

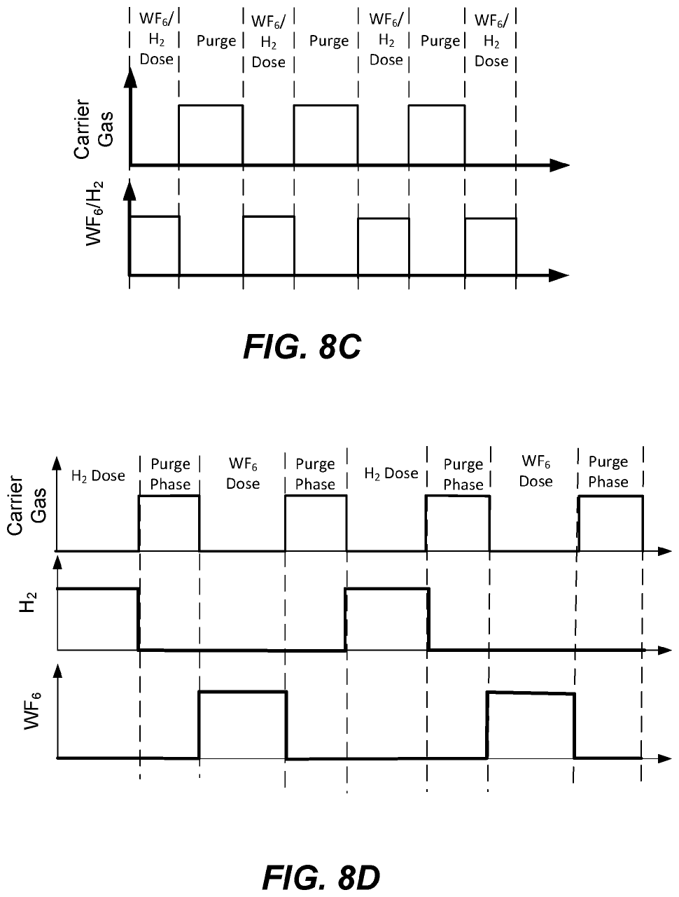

FIG. 5 shows a schematic example for metal layer formation according to various embodiments. FIG. 5 illustrates that a metal halide precursor and a reducing agent, e.g., WF₆ and H₂, may be provided into a deposition chamber to form a tungsten layer on bottom silicon in a substrate using an ALD or CVD process. Tungsten layer 504 may be selectively formed on an upper surface of crystalline silicon 502, without forming on dielectric sidewalls 506. During tungsten layer formation, a substrate may be exposed to WF₆ and H₂ co-flowing continuously. Alternately, WF₆ may be pulsed while H₂ flows continuously. Alternately, WF₆ and H₂ are pulsed sequentially without any overlap. The flow sequences for a precursor, a reducing agent, and a carrier gas according to various embodiments are further described in detail in FIGS. 8A-8D.

While WF₆ is shown as an example of metal halide precursor for tungsten layer deposition, other metal halide precursors, e.g., WCl₆, or WCl₅, may be pulsed together with hydrogen (H₂). For forming molybdenum, MoF₆, MoCl₆, or MoCl₅ may be used as a precursor. In some embodiments, hydrogen (H₂), silane (SiH₄), or their mixtures, may be used as a reducing agent.

In some embodiments, the gas flow rates for a metal halide precursor, e.g., WF₆, WCl₆, or WCl₅, and a reducing agent, e.g., H₂, or SiH₄, during tungsten layer formation may be controlled. In some embodiments, flow rate of a reducing agent is at least 10 times higher than the flow rate of a metal halide precursor. For example, the gas flow rate of H₂ may be controlled to be at least 10 times higher than the gas flow rate of WF₆ to achieve high H₂ flow rate condition. In some embodiments, the gas flow rate of H₂ to WF₆ may be set to be 10:1-10,000:1.

This high H₂ flow rate condition may be also applied to forming molybdenum layer. The gas flow rate of H₂ may be at least 10 times higher than the gas flow rate of molybdenum halide precursor, e.g., MoF₆, MoCl₆, or MoCl₅. In some embodiments, the gas flow rate of H₂ to MoF₆ is 10:1-10,000:1.

In this high H₂ flow rate condition, the rates of reactions (1) and (2) may be controlled such that reaction (1) lasts only for a limited time before reaction (2) predominates. In a situation where reaction (1) is quickly outcompeted, formation of wormhole or other defects may be minimized or significantly suppressed. Reaction (2) forms tungsten layer on a tungsten formed by a preceding reaction (1), without forming wormhole or other defects. In some embodiments, in a high H₂ flow rate condition, a resulting tungsten layer can include substantially reduced number of wormhole or other defects, which is beneficial in reducing short circuit, and/or variation in resistance, thereby improving device life and reliability.

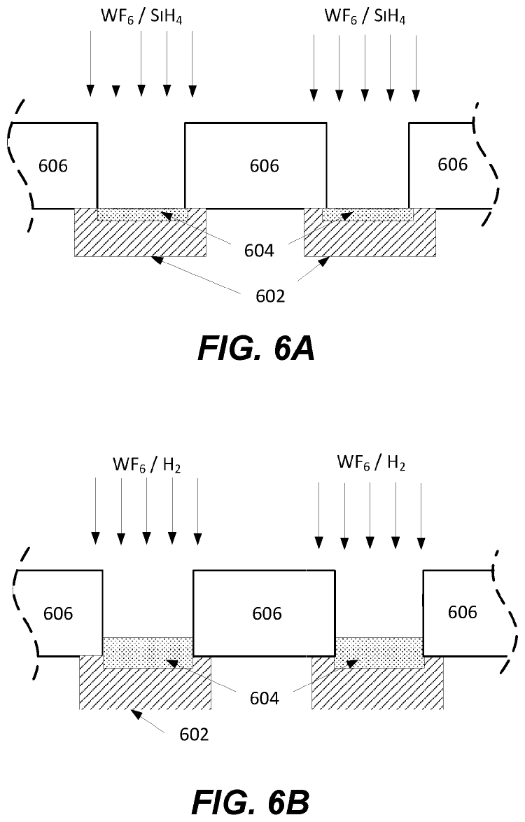

FIGS. 6A and 6B show schematic examples of forming a tungsten metal layer on bottom Si by combining two sequential steps of providing different sets of reactants according to various embodiments. In a first step as shown in FIG. 6A, a substrate is exposed to WF₆ and SiH₄. In some embodiments, WF₆ and SiH₄ may be delivered in a pulsed or continuous co-flow. Alternately WF₆ and SiH₄ may be pulsed sequentially. A tungsten layer 604 may be selectively formed on an upper surface of crystalline silicon 602, without forming tungsten on dielectric sidewalls 606. The flow rate of SiH₄ to WF₆ in a first gas mixture may be controlled to be at least 10:1. In some embodiments, the flow rate of SiH₄ to WF₆ may be set in the range of 10:1 to 10,000:1.

In some embodiments, introducing SiH₄ as a reducing agent in high flow rate may be favorable in that a bottom crystalline silicon consumption in SiH₄ reduction may not be as reactive as a silicon consumption in reaction (1) where H₂ only is used as a reducing agent. Therefore, wormhole or other defect formation may be suppressed or prevented compared to reaction (1) while tungsten layer is still formed on crystalline silicon.

In some embodiments, more than one reducing agent may be pulsed in a first step. For example, a mixture of SiH₄ and H₂ with a predetermined flow ratio may be used in replace of SiH₄. Addition of H₂ to SiH₄ may modify the reactivity of WF₆ with silicon. The flow rate of (SiH₄+H₂) to WF₆ may be controlled to be at least 10:1. In some embodiments, the flow rate of (SiH₄+H₂) to WF₆ may be set in the range of 10:1 to 10,000:1.

After the first step is complete, the first gas mixture may be purged to remove any gaseous reactants such as WF₆ and SiH₄ (or SiH₄+H₂) remaining in a deposition chamber. Subsequently, in a second step as shown in FIG. 6B, WF₆ and H₂ may be introduced to further form tungsten layer on a tungsten layer that was previously formed in a first step. The flow rate of H₂ to WF₆ in a second step may be controlled to be at least 10:1. In some embodiments, the flow rate of H₂ to WF₆ may be set in the range of 10:1 to 10,000:1. While FIGS. 6A and 6B describe steps to form tungsten layers with minimized or suppressed wormhole or other defect formation, molybdenum may also be formed according to embodiments shown in FIGS. 6A and 6B. For example, MoF₆, SiH₄, and H₂ may be pulsed to form a molybdenum layer on crystalline silicon.

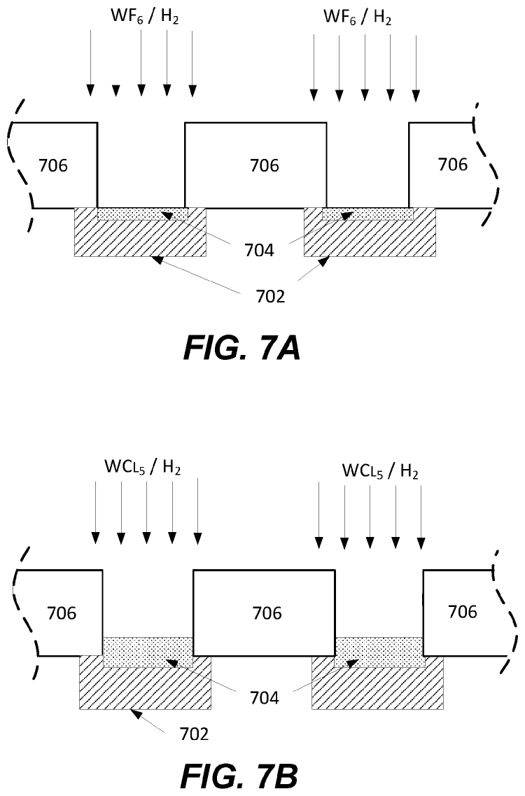

FIGS. 7A and 7B show schematic examples of forming tungsten layer on bottom Si by combining two sequential steps of providing different sets of reactants according to various embodiments. In some embodiments, in a first step as shown in FIG. 7A, a substrate including a feature in which tungsten is to be formed is exposed to a first set of reactants including WF₆ and H₂. WF₆ and H₂ may be pulsed or continuously co-flowed. Alternately WF₆ and H₂ may pulsed sequentially. A tungsten layer 704 may be selectively formed on an upper surface of crystalline silicon 702, without forming tungsten on dielectric sidewalls 706. In some embodiments, the flow rate of H₂ to WF₆ may be controlled to be at least 10:1. In some embodiments, the flow rate of H₂ to WF₆ may be 10:1 to 10.000:1.

In this high flow rate H₂ condition, formation of wormhole or other defects may be substantially suppressed or prevented. After a first step is complete, remaining WF₆ and H₂ in the gas phase may be purged to remove any unwanted reactions in a deposition chamber. Subsequently, in a second step as shown in FIG. 7B, a second set of reactants may be introduced into a deposition chamber. The second set of reactants may be different from the first set of reactants. For example, the second set of reactants may include tungsten pentachloride (WCl₅) and H₂. Chloride precursors such as WCl₅ may be advantageous over fluoride precursors such as WF₆ in that incorporation of fluorine (F) ion in tungsten raises its resistivity. Similar to the flow rate for a first set of reactants, the flow rate of H₂ to WCl₅ may be controlled to be at least 10:1. In some embodiments, the flow rate of H₂ to WCl₅ may be set in the range of 10:1 to 10,000:1. In some embodiments, tungsten hexachloride (WCl₆) may be used in a second step in replace of tungsten pentachloride (WCl₅) while maintaining the flow rate of H₂ to WCl₆. Use of tungsten chloride precursors such as tungsten pentachloride (WCl₅) or tungsten hexachloride (WCl₆) under high flow H₂ condition may be also advantageous in suppressing formation of wormhole or other defects.

In some embodiments, WCl₅ (or another WClₓ reactant) and H₂ may be pulsed or continuously co-flowed to form a tungsten layer on a substrate without using WF₆ or other gas reactants. Forming a tungsten layer only from WCl₅ and H₂ from the beginning of a deposition process may be advantageous to prevent the formation of defects such as wormholes.

It is noted that molybdenum layers may be formed according to embodiments shown in FIGS. 7A and 7B. For example, MoF₆ and H₂ may co-flow continuously or sequentially into a deposition chamber. After an optional purging, MoCl₅ (or MoCl₆) and H₂ may be pulsed to form molybdenum on a molybdenum formed by the reaction between MoF₆ and H₂.

After a metal layer such as tungsten or molybdenum is formed on a crystalline silicon according to various embodiments, the metal layer is annealed to convert a metal layer to a metal silicide layer. The annealing may be a rapid thermal annealing at between about 500-800° C. In some embodiments, the annealing may be undertaken in situ in a deposition chamber that was previously used for a metal layer formation without breaking vacuum. Chamber pressures of 1-100 Torr may be used. For in-situ annealing in a deposition chamber with multiple pedestals, a substrate in which a metal layer is to be formed may be positioned in one pedestal for metal layer formation. After metal is formed, the substrate with metal layer may be transferred to another pedestal in the same deposition chamber without breaking vacuum. Alternately a substrate with a metal layer may be removed from a deposition chamber for a subsequent annealing at a different annealing chamber. Compared with removing a substrate from a deposition chamber, an in-situ annealing may be beneficial in preventing formation of any undesirable oxide layer on the metal layer prior to annealing.

FIG. 8A shows an example of timing sequence for a pulsed CVD for depositing metal according to various embodiments. In the example of FIG. 8A, H₂ is continuously flowed. Although H₂ may be flowed alone, in some embodiments, a carrier gas, such as nitrogen (N₂), argon (Ar), helium (He), or other inert gases, may co-flow with H₂. For some embodiments, H₂ or a mixture of H₂ and a carrier gas co-flow continuously. For forming tungsten, WF₆ is pulsed into a deposition chamber housing a substrate on which tungsten is to be deposited. WF₆ is pulsed with intervals between the pulses. The intervals are labeled ‘purge’ as the continuous flow of H₂ (or H₂/Ar) has the effect of purging WF₆ from a chamber to outside. In some embodiments, pressure during a pulsed CVD may be below 20 Torr, e.g., 10 Torr, or below 10 Torr. Temperature during a pulsed CVD process may be the same as during the thermal decomposition of precursors, 250° C.-350° C.

FIG. 8B shows an example of timing sequence for a co-flow CVD for depositing metal according to various embodiments. Substrate temperature during co-flow CVD process may be 250° C.-350° C. For tungsten formation, WF₆ precursor and H₂ are pulsed such that they co-flow continuously into a deposition chamber where a substrate in which tungsten is to be formed is positioned. Co-flow may complete after a certain time when tungsten layer with predetermined thickness is formed. Although H₂ may flow alone, in some embodiments, argon (Ar) or other inert gas may co-flow with H₂. In some embodiments, the flow rate of H₂ to WF₆ is controlled to at least 10:1. In some embodiments, the frow rate of H₂ to WF₆ may be 10:1-10,000:1. Tungsten thickness may be monitored in-situ. Alternately a separate measurement may be undertaken to determine tungsten thickness.

FIG. 8C shows another example of time sequence for a co-flow CVD for depositing metal according to various embodiments. In some embodiments, a gas mixture including WF₆ and H₂ may be pulsed with intervals between the pulses followed by pulsing a carrier gas for tungsten deposition in between to purge WF₆ and H₂ in gas phase. In some embodiments, WF₆ and H₂ may form a gas mixture with a predetermined flow ratio. the flow rates of H₂ to WF₆ in a gas mixture during a co-flow CVD may be controlled to at least 10:1. In some embodiments, the frow rates of H₂ to WF₆ may be 10:1-10,000:1.

When a gas mixture (e.g., WF₆ and H₂) is pulsed to expose a substrate to WF₆ and H₂, WF₆ may react with silicon to form tungsten and SiF₄ in gas phase. Subsequently, WF₆ may react with H₂ to form tungsten on a tungsten formed from the reaction between WF₆ and Si, and HF in gas phase. At the end of pulsing of a gas mixture, a co-flow of WF₆ and H₂ stops, and tungsten is not formed anymore. A deposition chamber may include unreacted H₂ and/or WF₆. An inert gas such as argon (Ar) may be pulsed for a predetermined time to purge any remaining gas from a deposition chamber to prevent any unwanted gaseous reaction that may follow. After an inert gas purge, a gas mixture including WF₆ and H₂ is pulsed again to expose a substrate to WF₆ and H₂ thereby to form additional tungsten and HF in gas phase. In some embodiments, reaction between WF₆ and silicon may not complete in a first pulsing of WF₆/H₂. Instead, the reaction may continue in the subsequent pulsing(s).

Sequences of WF₆/H₂ pulse and a carrier gas pulse may be repeated until tungsten layer with a predetermined thickness is formed. Tungsten layer thickness may be monitored in-situ during tungsten layer formation. Alternately a separate measurement may be undertaken to determine tungsten thickness. Substrate temperature during a co-flow CVD may be 250° C.-350° C.

FIG. 8D shows an example of time sequence for ALD for depositing metal according to various embodiments. ALD process is a surface-mediated deposition technique in which doses of a reactants (e.g., a precursor and a reducing agents) and a carrier purge are sequentially introduced into a deposition chamber. FIG. 8D shows timing sequence for tungsten deposition, wherein a WF₆ precursor and a reducing agent (e.g., H₂) may be alternately pulsed into a deposition chamber. In FIG. 8D, H₂ is pulsed first to expose a substrate to H₂ in a deposition chamber. Subsequently a carrier gas is pulsed to remove H₂ that is not at or near the surface of a substrate from a chamber. During a carrier gas pulse, a deposition chamber may be under pressure of about 1 Torr. After purging is complete, WF₆ precursor is pulsed to expose a substrate on which tungsten metal is to be formed to WF₆ precursor. WF₆ may react with silicon to form tungsten on the surface of silicon. SiF₄ may be released in gas phase. In some embodiments, WF₆ may chemically react with H₂ that is at or near to a substrate to form tungsten on a tungsten already formed from the reaction between WF₆ and H₂, and HF in gas phase. After WF₆ pulsing completes, a carrier gas is pulsed again to purge a deposition chamber to remove any WF₆ and H₂ in gas phase. In some embodiments, the flow rates of H₂ to WF₆ may be controlled to at least 10:1. In some embodiments, the frow rates of H₂ to WF₆ may be 10:1-10,000:1.

Instead of pulsing H₂ first, in some embodiments, WF₆ is pulsed first to expose a substrate to WF₆, by which a reaction between WF₆ and silicon occurs, and tungsten is initially formed on the surface of silicon. Subsequently a carrier gas may be pulsed to remove any WF₆ that is not at or near to silicon. After a carrier gas pulsing, H₂ is pulsed to expose a substrate to H₂. In some embodiments, WF₆ may continue to react with Si in the presence of H₂ to form tungsten and SiF₄ in gas phase. In some embodiments, WF₆ may react with H₂ to form tungsten on a tungsten formed by the reaction between WF₆ and Si, and HF in gas phase. H₂ pulsing step is followed by a carrier gas pulsing to remove any gaseous phase that is not at or near to the surface of Si. In some embodiments, the flow rates of H₂ to WF₆ may be controlled to at least 10:1. In some embodiments, the frow rates of H₂ to WF₆ may be 10:1-10,000:1.

It should be noted that the y-axes in the example timing sequences in FIGS. 8A-8D do not necessarily have the same scale; rather, the timing sequence is given to demonstrate the relative pulse and purge durations. Also, it should be noted that any purge:dose duration in the example timing sequences in FIGS. 8A, 8C, and 8D do not necessarily reflect actual duration; rather, any purge:dose duration demonstrates a timing sequence between a metal halide precursor, a reducing agent, and a carrier gas.

It should be also noted that the example timing sequences in FIGS. 8A-8D can be used in forming molybdenum (Mo) layer. For example, Mo metal layer may be formed by a pulsed CVD process according to FIG. 8A by using MoF₆ precursor and H₂. In another example, Mo metal layer may be formed by a co-flow CVD process according to FIG. 8B by continuously pulsing MoF₆ and H₂. In another example, Mo metal layer may be formed by a co-flow CVD process according to FIG. 8C by continuously pulsing MoF₆ and H₂, and sequentially purging by a carrier gas between pulses for MoF₆/H₂. In yet another example, Mo metal layer may be formed by ALD process according to FIG. 8D by alternately and sequentially pulsing MoF₆, H₂ and a carrier gas.

According to various embodiments, one or more of the following advantages may be realized by the methods described herein. In some embodiments, metal layer such as tungsten or molybdenum layer is formed while significantly suppressing the formation of wormhole or other defects between at metal layer and underlying crystalline silicon. Control of these defects is responsible for improved device reliability. In some embodiments, following metal layer formation, a substrate with a metal layer may be annealed in a same chamber without being exposed to ambient atmosphere thereby preventing contamination and oxidation of metal layer. This in-situ annealing provides additional advantages of not requiring multiple process steps including capping metal deposition, annealing, stripping off capping metal, pre-clean before barrier meal or capacitor bottom electrode deposition. This in-situ annealing also improves production yield and reduces manufacturing cost.

In some embodiments, the metal silicide layer may be formed in quad-station module (QSM), ALTUS® W, or ALTUS® Halo, available from Lam Research Corp., of Fremont, California, or any of a variety of other commercially available processing systems. These products may include a deposition chamber including multiple pedestals. In some embodiments, a deposition station may include four pedestals, and first, second, and third pedestals may be used for selectively forming metal layer, while fourth pedestal may be used for a metal annealing for forming a metal silicide. This product configuration may maximize productivity of the process by reducing process integration steps and manufacturing cost.

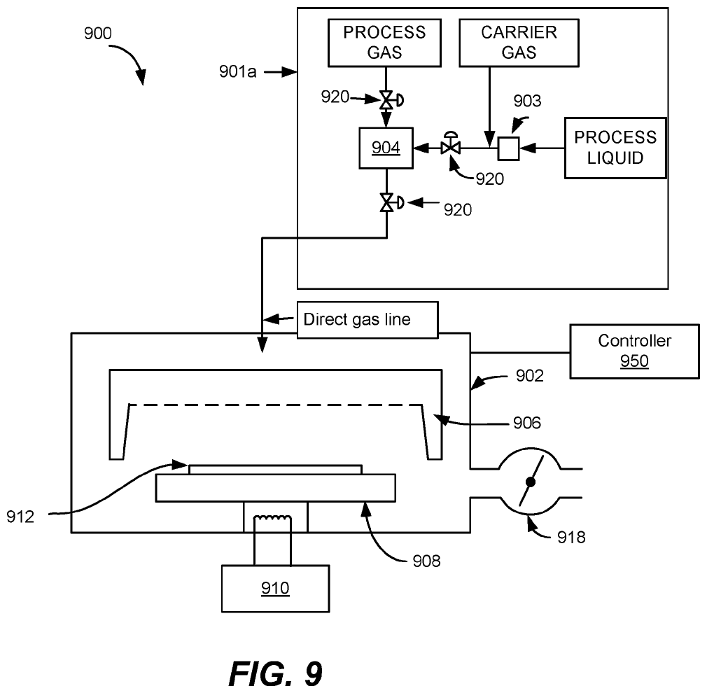

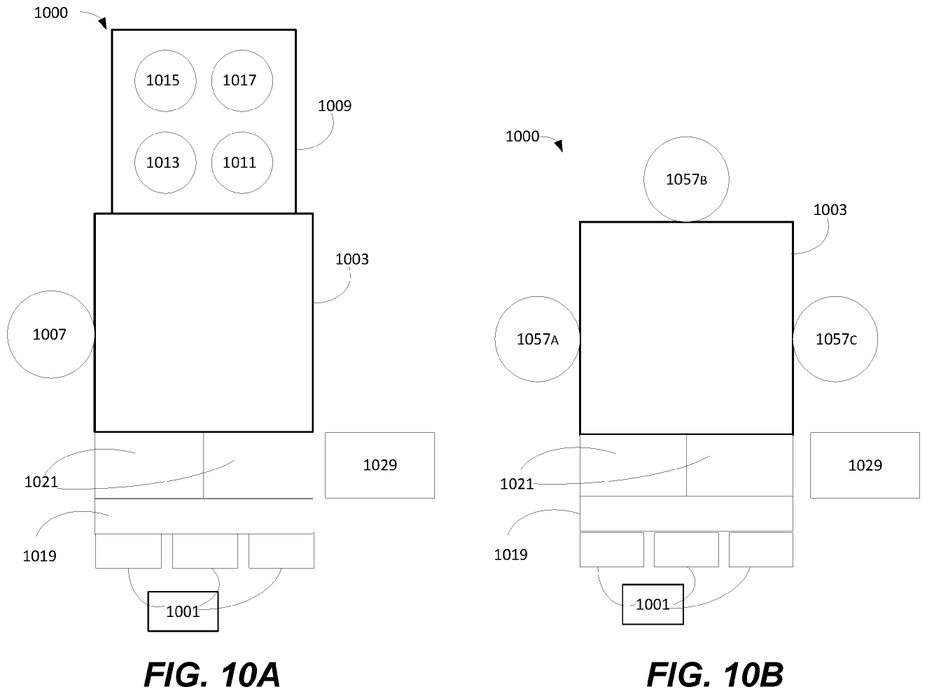

FIG. 9 depicts a schematic illustration of an embodiment of a process station 900 having a process chamber 902 for maintaining a low-pressure environment. In some embodiments, a plurality of process stations may be included in a common low-pressure process tool environment. For example, FIG. 10A depicts an embodiment of a processing tool 1000. In some embodiments, one or more hardware parameters of the process station 900, including those discussed in detail below, may be adjusted programmatically by one or more computer controller (e.g., controller 950). In some other embodiments, a process chamber may be a single station chamber.

In some embodiments, the process station 900 may include an ALD process station, and fluidly communicates with reactant delivery system 901a for delivering process gases to a distribution showerhead 906. Reactant delivery system 901a includes a mixing vessel 904 for blending and/or conditioning process gases, such as a W precursor-containing gas, Mo precursor-containing gas, a hydrogen-containing gas, an argon or other carrier gas, or other reactant-containing gas, for delivery to the showerhead 906. One or more mixing vessel inlet valves 920 may control introduction of process gases to mixing vessel 904. In various embodiments, deposition of a W layer or Mo layer is performed in the process station 900 and in some embodiments, other operations such as in-situ clean may be performed in the same or another station of the processing tool 1000 including multiple stations as further described below with respect to FIG. 10A.

As an example, the embodiment of FIG. 9 includes a vaporization point 903 for vaporizing liquid reactant to be supplied to the mixing vessel 904. In some embodiments, vaporization point 903 may be a heated vaporizer. In some embodiments, a liquid precursor or liquid reactant may be vaporized at a liquid injector (not shown). For example, a liquid injector may inject pulses of a liquid reactant into a carrier gas stream upstream of the mixing vessel 904. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 903. In one scenario, a liquid injector may be mounted directly to mixing vessel 904. In another scenario, a liquid injector may be mounted directly to showerhead 906.

In some embodiments, a liquid flow controller (LFC) upstream of vaporization point 903 may be provided for controlling a mass flow of liquid for vaporization and delivery to process chamber 902. For example, the LFC may include a thermal mass flow meter (MFM) located downstream of the LFC. A plunger valve of the LFC may then be adjusted to be responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 906 distributes process gases toward a substrate 912. In the embodiment shown in FIG. 9, a substrate 912 is located beneath the showerhead 906 and is shown resting on a pedestal 908. Showerhead 906 may have any suitable shape and may have any suitable number and arrangement of ports for distributing process gases to a substrate 912.

In some embodiments, a pedestal 908 may be raised or lowered to expose substrate 912 to a volume between the substrate 912 and the showerhead 906. In some embodiments, pedestal 908 may be temperature controlled via heater 910. A pedestal 908 may be set to any suitable temperature, such as between about 300° C. and about 500° C. during operations for performing various disclosed embodiments. It will be appreciated that, in some embodiments, pedestal height may be adjusted programmatically by a suitable controller 950. At the conclusion of a process phase, a pedestal 908 may be lowered during another substrate transfer phase to allow removal of a substrate 912 from a pedestal 908.

In some embodiments, a position of showerhead 906 may be adjusted relative to pedestal 908 to vary a volume between the substrate 912 and the showerhead 906. Further, it will be appreciated that a vertical position of a pedestal 908 and/or a showerhead 906 may be varied by any suitable mechanism within the scope of the present disclosure. In some embodiments, pedestal 908 may include a rotational axis for rotating an orientation of a substrate 912. It will be appreciated that, in some embodiments, one or more of these example adjustments may be performed programmatically by one or more suitable controller (e.g., computer controller 950). The controller 950 may include any of the features described below with respect to controller 950 of FIG. 9.

In some embodiments, instructions for a controller 950 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of an inert and/or a reactant gas (e.g., a W or Mo precursor, H₂, or SiH₄ etc.), instructions for setting a flow rate of a carrier gas (such as argon), and time delay instructions for the first recipe phase. A second, subsequent recipe phase may include instructions for modulating or stopping a flow rate of an inert and/or a reactant gas, and instructions for modulating a flow rate of a carrier or purge gas and time delay instructions for the second recipe phase. A third recipe phase may include instructions for modulating a flow rate of a second reactant gas such as H₂, instructions for modulating the flow rate of a carrier or purge gas, and time delay instructions for the third recipe phase. A fourth, subsequent recipe phase may include instructions for modulating or stopping a flow rate of an inert and/or a reactant gas, and instructions for modulating a flow rate of a carrier or purge gas and time delay instructions for the fourth recipe phase. It will be appreciated that these recipe phases may be further subdivided and/or iterated in any suitable way within the scope of the present disclosure.

Further, in some embodiments, pressure control for the process station 900 may be provided by a butterfly valve 918. As shown in the embodiment of FIG. 9, a butterfly valve 918 throttles a vacuum provided by a downstream vacuum pump (not shown). However, in some embodiments, pressure control of the process station 900 may also be adjusted by varying a flow rate of one or more gases introduced to the process station 900.

FIG. 10A and FIG. 10B show examples of processing systems. FIG. 10A shows an example of a processing tool including multiple stations. The processing tool 1000 includes a transfer module 1003. The transfer module 1003 provides a clean, vacuum environment to minimize risk of contamination of substrates being processed as they are moved between various modules. Mounted on the transfer module 1003 is a chamber 1009 (e.g., a multi-station chamber) capable of performing in-situ clean and/or ALD processes described above.

The chamber 1009 may include multiple stations 1011, 1013, 1015, and 1017 that may sequentially perform operations in accordance with disclosed embodiments. For example, the chamber 1009 may be configured such that stations 1011, and 1013 perform an in-situ clean of the substrate using a diluted hydrogen fluoride, as well as subsequent deposition of metal layer. For example, tungsten layer may be formed using the WF₆ precursor and H₂. That way, stations 1011 and 1013 may be configured to do parallel processing of a substrate, with each station performing cleaning and deposition processes sequentially. Stations 1015 and 1017 may be configured to receive a substrate with a metal layer respectively formed in stations 1011 and 1013 to perform annealing to convert a metal layer to a metal silicide layer without contaminating a substrate to ambient atmosphere. In another example, the chamber 1009 may be configured such that station 1011 performs in-situ clean, stations 1013 and 1015 perform metal layer deposition, and station 1017 performs annealing of metal layer. In another example, the chamber 1009 may be configured such that stations 1011, 1013, and 1015 do parallel processing of substrates, with each station performing multiple processes including in-situ cleaning and metal deposition sequentially. After metal layer deposition in the stations 1011, 1013, and 1015, station 1017 may receive substrates from stations 1013, 1015 and 1017 for annealing.

Two or more stations may be included in a multi-station chamber, e.g., 2-6, with the operations appropriately distributed. For example, a two-station chamber may be configured to perform cleaning of a substrate in a first station followed by metal layer deposition in a second station. Stations may include a heated pedestal or substrate support, one or more gas inlets or showerhead or dispersion plate.

Also mounted on the transfer module 1003 may be a module 1007. In some embodiments, a preclean as described above may be performed in the module 1007, after which the substrate is transferred under vacuum to another module (not shown here) similar to the module 1007 or the chamber 1009 for ALD.

The processing tool 1000 also includes one or more wafer source modules 1001, where wafers are stored before and after processing. An atmospheric robot (not shown) in the atmospheric transfer chamber 1019 may first remove wafers from the source modules 1001 to loadlocks 1021. A wafer transfer device (generally a robot arm unit) in the transfer module 1003 moves the wafers from loadlocks 1021 to and among the modules mounted on the transfer module 1003.

FIG. 10B is an embodiment of a processing tool 1000, as described in 10A. The processing tool 1000 in FIG. 10B has wafer source modules 1001, a transfer module 1003, atmospheric transfer chamber 1019, and loadlocks 1021, as described above with reference to FIG. 10A. The system in FIG. 10B has three single station modules 1057A-1057C. The processing tool 1000 may be configured to sequentially perform operations in accordance with some embodiments herein. For example, the station modules may be configured so that a single station module 1057A performs a cleaning operation, a single station module 1057B performs metal formation using, for example, a metal halide precursor, and a single station module 1057C performs in-situ annealing. Station modules may include a heated pedestal or substrate support, one or more gas inlets or showerhead or dispersion plate as described above with reference to FIG. 9.

In various embodiments, a controller 1029 (e.g., a system controller) is employed to control process conditions during deposition. The controller 1029 will typically include one or more memory devices and one or more processors. A processor may include a CPU or computer, analog and/or digital input/output connections, stepper motor controller boards, etc.

The controller 1029 may control all the activities of the apparatus. The controller 1029 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 1029 may be employed in some embodiments.

Typically, there will be a user interface associated with the controller 1029. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general-purpose processor. System control software may be coded in any suitable computer readable programming language.

The computer program code for controlling the Mo precursor pulses, hydrogen pulses, and argon flow, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the controller 1029. The signals for controlling the process are output on the analog and digital output connections of the deposition apparatus.

The system software may be designed or configured in many ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller 1029 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 1029, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 1029, in some implementations, may be a part of or coupled to a computer that is integrated with, coupled to the system, otherwise networked to the system, or a combination thereof. For example, the controller 1029 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. The parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a PVD chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller 1029 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

1. A method comprising:
providing a feature having a feature bottom and feature sidewalls, wherein the feature bottom comprises a crystalline silicon surface and the feature sidewalls comprise oxide or nitride surfaces;
exposing the feature to a metal halide precursor flow comprising a metal halide precursor and a reducing agent flow comprising a reducing agent to thereby selectively form a metal layer on the crystalline silicon surface, wherein the metal halide precursor flow and the reducing agent flow have a flow rate ratio of at least 10:1; and
annealing the metal layer to form a metal silicide layer.

2. The method of claim 1, further comprising:
prior to exposing the feature to the metal halide precursor flow, cleaning the feature bottom and the feature sidewalls.

3. The method of claim 1, wherein the metal halide precursor comprises a metal chloride or a metal fluoride.

4. The method of claim 3, wherein the metal halide precursor comprises tungsten hexafluoride, tungsten pentachloride, molybdenum hexafluoride, molybdenum pentachloride.

5. The method of claim 1, wherein the metal layer comprises tungsten or molybdenum.

6. The method of claim 1, wherein the reducing agent comprises hydrogen, silane, or a combination thereof.

7. The method of claim 1, wherein the ratio ranges from about 10:1 to about 10,000:1.

8. The method of claim 1, wherein the metal layer ranges in thickness from about 2-20 nm.

9. The method of claim 1, wherein crystalline silicon of the crystalline silicon surface is doped or undoped single crystalline silicon crystal or doped or undoped polycrystal.

10. The method of claim 1, wherein the annealing of the metal layer is undertaken between about 500-800° C.

11. The method of claim 1, wherein the annealing of the metal layer is undertaken under pressures ranging 1-100 Torr.

12. The method of claim 1, wherein the metal halide precursor flow and the reducing agent flow are alternated to form the metal layer by atomic layer deposition.

13. The method of claim 1, wherein the metal halide precursor flow and the reducing agent flow are co-flowed to form the metal layer by chemical vapor deposition.

14. The method of claim 1, wherein the metal halide precursor flow is pulsed and the reducing agent flow is continuous to form the metal layer by pulsed chemical vapor deposition.

15. The method of claim 1, wherein the metal silicide layer forms an ohmic contact with the crystalline silicon surface.

16. The method of claim 1, wherein the metal silicide layer comprises tungsten silicide or molybdenum silicide.

17. A method comprising:
providing a feature having a feature bottom and feature sidewalls, wherein the feature bottom comprises a crystalline silicon surface and the feature sidewalls comprise oxide or nitride surfaces;
exposing the feature to a first metal halide precursor flow comprising a first metal halide precursor, and a first reducing agent flow comprising a first reducing agent to thereby selectively form a first metal layer on the crystalline silicon surface, wherein the first metal halide precursor flow and the first reducing agent flow have a flow rate ratio of at least 10:1;
providing a second metal halide precursor flow comprising a second metal halide precursor, and a second reducing agent flow comprising a second reducing agent to the first metal layer to form a second metal layer, wherein the second metal halide precursor flow and the second reducing agent flow have a flow rate ratio of at least 10:1; and
annealing the second metal layer to form a metal silicide layer.

18. The method of claim 17, wherein the first metal halide precursor and the second metal halide precursor are selected respectively from tungsten hexafluoride, tungsten pentachloride, molybdenum hexafluoride, and molybdenum pentachloride.

19. The method of claim 17, wherein the first reducing agent and the second reducing agent are selected respectively from hydrogen, silane, or a combination thereof.

20. The method of claim 17, wherein the metal silicide layer comprises tungsten silicide or molybdenum silicide.

21. The method of claim 17, wherein the first and second metal halide precursors and the first and second reducing agents are supplied by chemical vapor deposition or atomic layer deposition.
